(19) United States
(12) Patent Application Publication
(10) Pub. No.: US 2026/0112861 A1
(43) Pub. Date: Apr. 23, 2026

(54) DRIVER WITH CHARGE CANCELLATION

(71) Applicant: TEXAS INSTRUMENTS INCORPORATED, Dallas, TX (US)

(72) Inventors: Venkata Ramanan R, Bengaluru (IN); Arkaprabha DAS, Kolkata (IN); Shreenidhi PATIL, New Delhi (IN)

(21) Appl. No.: 19/338,747

(22) Filed: Sep. 24, 2025

(30) Foreign Application Priority Data
Oct. 18, 2024 (IN) 202441079134

(51) Int. Cl. H01S 5/042

(52) U.S. Cl. CPC H01S 5/0428

(57) ABSTRACT

An electronic circuit includes: an output terminal; a first transistor having a current path terminal coupled to the output terminal; a second transistor having a current path terminal coupled between the output terminal and the current path terminal of the first transistor; a driver circuit having an input and an output, the output of the driver circuit coupled to a control terminal of the second transistor; an analog buffer having an output coupled to a control terminal of the first transistor; and an auxiliary circuit configured to apply charge cancellation to the control terminal of the first transistor responsive to a signal at the input of the driver circuit.

### CROSS-REFERENCE TO RELATED APPLICATIONS

This application claims priority to India Provisional Application No. 202441079134, filed Oct. 18, 2024, entitled “High speed pulsed laser driver with reduced overshoot and nano second settling,” which is hereby incorporated herein by reference in its entirety.

### TECHNICAL FIELD

The present disclosure relates generally to an electronic system and method, and, in particular embodiments, to a driver with charge cancellation.

### BACKGROUND

An output current driver may be used in a variety of applications, such as a laser driver.

### SUMMARY

In one example, an electronic circuit includes: an output terminal; a first transistor having a current path terminal coupled to the output terminal; a second transistor having a current path terminal coupled between the output terminal and the current path terminal of the first transistor; a driver circuit having an input and an output, the output of the driver circuit coupled to a control terminal of the second transistor; an analog buffer having an output coupled to a control terminal of the first transistor; and an auxiliary circuit configured to apply charge cancellation to the control terminal of the first transistor responsive to a signal at the input of the driver circuit.

In another example, an electronic circuit includes: an output terminal; a first transistor having a current path terminal coupled to the output terminal; a second transistor having a current path terminal coupled between the output terminal and the current path terminal of the first transistor; a buffer chain having an input and an output, the output of the buffer chain coupled to a control terminal of the second transistor; a non-overlapping driver circuit having an input and an output, the input of the non-overlapping driver circuit coupled to the output of the buffer chain; and a capacitor coupled between the output of the non-overlapping driver circuit and the control terminal of the first transistor.

In yet another example, a system includes: a controller; and a laser driver coupled to the controller. The laser driver includes: a first transistor and a second transistor, the first transistor having a control terminal, and the second transistor having a control terminal; and control circuitry having a first output terminal and a second output terminal. The first output terminal is coupled to control terminal of the first transistor. The second output terminal is coupled to the control terminal of the second transistor. The control circuitry is configured to: provide a first charge to the first output terminal; provide a second charge to the second output terminal based on an output of the controller; and while providing the first charge to the first output terminal and the second charge at the second output terminal, apply a charge cancellation at the first output terminal responsive to the second charge at the second output terminal.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a circuit schematic of a system, in accordance to an embodiment of the present disclosure;

FIG. 2 is a timing diagram showing signals related to a laser driver, in accordance to an embodiment of the present disclosure;

FIG. 3 is a diagram of a non-overlapping driver circuit, in accordance to an embodiment of the present disclosure;

FIG. 4 is a schematic diagram of a low dropout regulator (LDO), in accordance to an embodiment of the present disclosure;

FIG. 5A is a schematic diagram of an analog buffer, in accordance to an embodiment of the present disclosure;

FIG. 5B is a schematic diagram of another analog buffer, in accordance to an embodiment of the present disclosure;

FIG. 6 is a flowchart of a laser driver method, in accordance to an embodiment of the present disclosure; and

FIG. 7 is a flowchart of another laser driver method, in accordance to an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” or “an example” in this description indicate that a particular configuration, structure or feature described in relation to the embodiment is included in at least one embodiment. Consequently, phrases such as “in one embodiment” or “in one example” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Some embodiments relate to complementary drivers with charge cancellation for a laser driver or other current driver.

Output currents in a high-speed laser driver may be prone to high overshoot and poor settling performance.

An example laser driver includes a current mirror with a first switch and a second switch in series. Due to internal capacitances of the first switch and the second switch, the gate voltage at the control terminal of the first switch can increase the gate voltage at the control terminal of the second switch or vice versa. Such increases to the gate voltage of the first switch and/or the gate voltage of the second switch result in increased overshoot and settling times In an example laser driver or other current driver, a first transistor and a second transistor in series may be used to control output current. In such examples, the first transistor may be part of a current mirror and the second transistor may provide protection and support a target switching speed (e.g., 250 MHz). In some examples, the first transistor is a low-voltage (e.g., below 5V) transistor and the second transistor is a high-voltage (e.g., 18V or higher) transistor. In some examples, the output (e.g., IOUT herein) of a laser driver circuit has high voltage and the second transistor is a cascode transistor for the first transistor, which protects the laser driver output from high-voltage transients.

In some embodiments, to account for internal capacitances of the first transistor and the second transistor, control circuitry for the first transistor and the second transistor may perform charge cancellation at the control terminal of the first transistor and/or the second transistor. The control circuitry includes, for example, a first driver circuit, an analog buffer, and an auxiliary circuit. In some examples, the auxiliary circuit includes a second driver circuit and a capacitor. In some examples, each of the first driver circuit and the second driver circuit is non-overlapping driver circuit to avoid shoot through current. The first driver circuit has an input and an output. The output of the first driver circuit is coupled to a control terminal of the second transistor. The analog buffer has an output coupled to the control terminal of the first transistor. The auxiliary circuit has an output coupled to the control terminal of the first transistor. In some examples, the control circuitry (may perform charge cancellation at the control terminal of the first transistor responsive to a signal at an input of the first driver circuit.

In some examples, the control circuitry has: a first output terminal coupled to the control terminal of the first transistor (e.g., the current mirror transistor); and a second output terminal coupled to the control terminal of the second transistor (e.g., a switching/protection transistor). In such examples, the control circuitry is configured to: provide a first charge to the first output terminal; provide a second charge to the second output terminal (e.g., based on signaling from a time-of-flight controller or other controller); and while providing the first charge to the first output terminal and the second charge at the second output terminal, apply a charge cancellation at the first output terminal responsive to the second charge at the second output terminal. With the control circuitry described herein, the voltages at the control terminals of the first transistor and the second transistor are regulated (e.g., using charge cancellation) to account for internal capacitances of the first and second transistors. Such regulation reduces output current overshoot and output current settling time of a laser driver or other current driver.

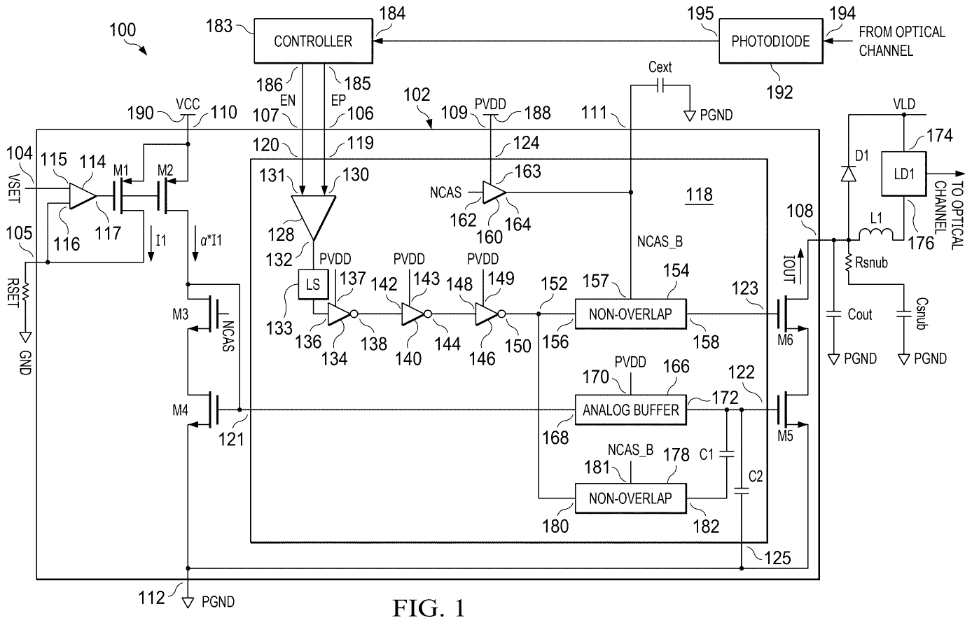

FIG. 1 is a circuit schematic of a system 100, in accordance to an embodiment of the present disclosure. The system 100 includes a laser driver circuit 102, a capacitor Cout, a capacitor Cext, a laser diode LD1, an inductor L1, a controller 183, a photodiode 192, a resistor RSET, a resistor Rsnub, and a capacitor Csnub in the arrangement shown. In some examples, the system 100 includes a level shifter (LS) 133. In the example of FIG. 1, the inductor L1 represents inductance of the laser diode LD1 and/or inductance of traces coupling the laser diode LD1 to the laser driver circuit 102. In some examples, the laser driver circuit 102 is an integrated circuit (IC) separate from the controller 183, the photodiode 192, the laser diode LD1, the inductor L1, the diode D1, the capacitor Cout, the capacitor Cext, the resistor Rsnub, and the capacitor Csnub. In other examples, controller 183 may be included in an IC with the laser driver circuit 102. In some embodiments, the controller 183 is a time-of-flight (TOF) controller.

In some embodiments, controller 183 may be implemented as a generic or custom processor or controller coupled to a memory and configure to execute instructions in such memory. In some embodiments, controller 183 may be implemented using a field programmable gate array (FPGA). In some embodiments, controller 183 includes combinational logic, sequential logic, programmable logic (e.g., in combination with program memory), or the like, or a combination thereof. In some embodiments, controller 183 includes a state machine. In some embodiments, controller 183 includes a hardware accelerator. In some embodiments, controller 183 is implemented using (e.g., only) synthesized logic. Other implementations may also possible.

In the example of FIG. 1, the resistor RSET has a first terminal and a second terminal. The laser driver circuit 102 has a first terminal 104, a second terminal 105, a third terminal 106, a fourth terminal 107, a fifth terminal 108, a sixth terminal 109, a seventh terminal 110, an eighth terminal 111, and a ninth terminal 112. The controller 183 has a first terminal 184, a second terminal 185, and a third terminal 186. The photodiode 192 has an input 194 and an output 195. The laser diode LD1 has a first terminal 174 and a second terminal 176. In some examples, the laser diode LD1 may be represented as a diode, a capacitor, and a resistor, where the resistor is in series with the diode between first terminal 174 and the second terminal 176, and the capacitor is in parallel with the diode and resistor. The inductor L1 has a first terminal and a second terminal. The diode D1 has an anode and a cathode. The resistor Rsnub has a first terminal and a second terminal. The capacitor Csnub has a first terminal and a second terminal. The capacitor Cout has a first terminal and a second terminal. The capacitor Cext has first terminal and a second terminal.

In some examples, the laser driver circuit 102 includes an operational amplifier 114, transistors M1 to M6, and control circuitry 118 in the arrangement shown. In some examples, the transistor M5 is a low-voltage (e.g., below 5V) transistor and the transistor M6 is a high-voltage (e.g., 18V) transistor to provide the current mirror formed using transistors M3 to M5. The operational amplifier 114 has a first terminal 115, a second terminal 116, and a third terminal 117. Each of the transistors M1 to M6 has a respective first current path terminal (e.g., a drain terminal), a second current path terminal (e.g., a source terminal), and a control terminal (e.g., a gate terminal). In the example of FIG. 1, the transistors M1 and M2 are p-channel metal oxide semiconductor (PMOS) transistors. The transistors M3 to M6 are n-channel metal oxide semiconductor (NMOS) transistors. The control circuitry 118 includes a first terminal 119, a second terminal 120, a third terminal 121, a fourth terminal 122, a fifth terminal 123, a sixth terminal 124, and a seventh terminal 125.

In the example of FIG. 1, the control circuitry 118 includes a differential amplifier 128, inverters 134, 140, 146, a first non-overlapping driver circuit 154, an analog buffer 166, a second non-overlapping driver circuit 178, capacitors C1 and C2, and a low-dropout regulator (LDO) 160. The differential amplifier 128 has a first input 130, a second input 131, and an output 132. The inverter 134 has an input 136, a power terminal 137, and an output 138. The inverter 140 has an input 142, a power terminal 143, and an output 144. The inverter 144 has an input 148, a power terminal 149, and an output 150. The first non-overlapping driver circuit 154 has an input 156, a power terminal 157, and an output 158. The second non-overlapping driver circuit 178 has an input 180, a power terminal 181, and an output 182. The analog buffer 166 has an input 168, a power terminal 170, and an output 172. Each of the capacitors C1 and C2 has a respective first terminal and a respective second terminal. The LDO 160 has a first output 162, a power terminal 163, and a second output 164. In the example of FIG. 1, there are different voltage domains for noise isolation. A first voltage domain is set by a first supply voltage (VCC) and first ground (GND). A second voltage domain is set by a second supply voltage (PVDD) and a second ground (PGND). Compared to second voltage domain, the first voltage domain is clean. Another supply voltage (NCAS_B herein) is obtained from PVDD and is used to regulate voltage at the control terminals of the transistors M5 and M6. Use of the different voltage domains provides noise immunity. For example, when the transistor M6 is turned OFF or ON, a large di/dt current flows via PGND in high current (>5 A) and high speed (1 ns rise time) laser drivers. Due to package inductance, PGND will “bounce” (overshoot or undershoot by ˜<150 pH) and be noisy. To avoid PGND noise, some components (e.g., the operational amplifier 114 and the differential amplifier 128 are in first voltage domain (the VCC/GND domain), which is cleaner than the second voltage domain (the PVDD/PGND domain). In some examples, the controller 183 is in the first voltage domain. The inverters 134, 140, 146, the LDO 160, and the analog buffer 166 are in the second voltage domain. The LDO 160 provides NCAS_B. The first non-overlapping driver circuit 154 and the second non-overlapping driver circuit 154 use NCAS_B and PGND. In FIG. 1, the ground for each component is not always represented but can be assumed (i.e., components powered by VCC use GND as ground, components powered by PVDD use PGND as ground, and components powered by NCAS_B use PGND as ground).

In the example of FIG. 1, the first terminal of the resistor RSET is coupled to the second terminal 105 of the laser driver circuit 102. The second terminal of the resistor RSET is coupled to ground or a ground terminal. The third terminal 106 of the laser driver circuit 102 is coupled to the second terminal 185 of the controller 183. The fourth terminal 107 of the laser driver circuit 102 is coupled to the third terminal 186 of the controller 183. The fifth terminal 108 of the laser driver circuit 102 is coupled to the first terminal of the inductor L1, the anode of the diode D1, the first terminal of the capacitor Cout, and first terminal of the resistor Rsnub. The sixth terminal 109 of the laser driver circuit 102 is coupled to a PVDD terminal 188. The seventh terminal 110 of the laser driver circuit 102 is coupled to a VCC terminal 190. The eighth terminal 111 of the laser driver circuit 102 is coupled to the first terminal of the capacitor Cext. The second terminal of the capacitor Cext is coupled to a PGND terminal. The ninth terminal 112 of the laser driver circuit 102 is coupled to a PGND terminal.

The second terminal of the resistor Rsnub is coupled to the first terminal of the capacitor Csnub. The second terminal of the capacitor Csnub is coupled to a PGND terminal. The cathode terminal of the diode D1 is coupled to the first terminal 174 of the laser diode LD1. The second terminal 176 of the laser diode LD1 is coupled to the second terminal of the inductor L1.

The first terminal 115 of the operational amplifier 114 is coupled to the first terminal 104 of the laser driver circuit 102. The second terminal 116 of the operational amplifier 114 is coupled to the second terminal 105 of the laser driver circuit 102 and the second current path terminal of the transistor M1. In some examples, the operational amplifier 114 uses VCC for power and uses AGND as ground. The third terminal 117 of the operational amplifier 114 is coupled to the control terminals of the transistors M1 and M2. The first current path terminals of the transistors M1 and M2 are coupled to the seventh terminal 110 of the laser driver circuit 102. The second current path terminal of the transistor M2 is coupled to the first current path terminal of the transistor M3, the control terminal of the transistor M4, and the third terminal 121 of the control circuitry 118. The second current path terminal of the transistor M3 is coupled to the first current path terminal of the transistor M4. The control terminal of the transistor M3 is coupled to the first output 162 of the LDO 160 and receives a voltage NCAS. The second current path terminal of the transistor M4 is coupled to the ninth terminal 112 of the laser driver circuit 102. The second current path terminal of the transistor M5 is also coupled to the ninth terminal 112 of the laser driver circuit 102. The first current path terminal of the transistor M5 is coupled to the second current path terminal of the transistor M6. The first current path terminal of the transistor M6 is coupled to the fifth terminal 108 of the laser driver circuit 102. Sometimes the fifth terminal 108 of the laser driver circuit is referred to as an output terminal of the laser driver circuit 102 herein.

The first terminal 119 of the control circuitry 118 is coupled to the third terminal 106 of the laser driver circuit 102. The second terminal 120 of the control circuitry 118 is coupled to the fourth terminal 107 of the laser driver circuit 102. The third terminal 121 of the control circuitry 118 is coupled to the control terminal of the transistor M4. The fourth terminal 122 of the control circuitry 118 is coupled to the control terminal of the transistor M5. The fourth terminal 122 is sometimes referred to herein as a first output terminal of the control circuitry 118. The fifth terminal 123 of the control circuitry 118 is coupled to the control terminal of the transistor M6. The fifth terminal 123 is sometimes referred to herein as a second output terminal of the control circuitry 118. The sixth terminal 124 of the control circuitry 118 is coupled to the sixth terminal 109 of the laser driver circuit 102. The seventh terminal 125 of the control circuitry 118 is coupled to the ninth terminal 112 of the laser driver circuit 102.

The first output 162 of the LDO 160 provides NCAS (e.g., to the control terminal of the transistor M3). The power terminal 163 of the LDO 160 is coupled to the sixth terminal 124 of the control circuitry 118. The first input 130 of the differential amplifier 128 is coupled to the first terminal 119 of the control circuitry 118. The second input 131 of the differential amplifier 128 is coupled to the second terminal 120 of the control circuitry 118. The output 132 of the differential amplifier 128 is coupled to the input 136 of the inverter 134. In some examples, the level shifter 133 is between the output 132 of the differential amplifier 128 and the input 136 of the inverter 134.

The power terminal 137 of the inverter 134 is coupled to the sixth terminal 124 of the control circuitry 118. The output 138 of the inverter 134 is coupled to the input 142 of the inverter 140. The power terminal 143 of the inverter 140 is coupled to the sixth terminal 124 of the control circuitry 118. The output 144 of the inverter 140 is coupled to the input 148 of the inverter 146. The power terminal 149 of the inverter 146 is coupled to the sixth terminal 124 of the control circuitry 118. The output 150 of the inverter 146 is coupled to the input 156 of the first non-overlapping driver circuit 154 and to the input 180 of the second non-overlapping driver circuit 178. The power terminal 157 of the first non-overlapping driver circuit 154 is coupled to the second output 164 of the LDO 160. The output 158 of the first non-overlapping driver circuit 154 is coupled to the fifth terminal 123 of the control circuitry.

The input 168 of the analog buffer 166 is coupled to the third terminal 121 of the control circuitry 118. The power terminal 170 of the analog buffer 166 is coupled to the sixth terminal 124 of the control circuitry 118. The output 172 of the analog buffer 166 is coupled to the fourth terminal 122 of the control circuitry 118, the second terminal of the capacitor C1, and the first terminal of the capacitor C2. The first terminal of the capacitor C1 is coupled to the output 182 of the second non-overlapping driver circuit 178. The second terminal of the capacitor C2 is coupled to the seventh terminal 125 of the control circuitry 118.

In some examples, the inverters 134, 140, 146 are components of a buffer chain. In different embodiments, the number of inverters in the buffer chain may vary. In some examples, the size of the inverters in the buffer chain may increase from left to right (sometimes referred to as fanning out) to support driving the transistor M6. In some examples, the buffer chain and first non-overlapping driver circuit 154 are referred to as a first driver circuit herein. In such examples, the input 136 of the inverter 134 is the input terminal of the first driver circuit, and the output 158 of the first non-overlapping driver circuit 154 is the output terminal of the first driver circuit. In such examples, the first driver circuit has an intermediate terminal 152 between the output 150 of the inverter 146 and the input 156 of the first non-overlapping driver circuit 154. The intermediate terminal 152 is coupled to the input 180 of the second non-overlapping driver circuit 178. In some examples, the second non-overlapping driver circuit 178 and the capacitor C1 are referred to as an auxiliary circuit herein. In such examples, the input 180 of the second non-overlapping driver circuit 178 is an input terminal of the auxiliary circuit, and the second terminal of the capacitor C1 is an output terminal of the auxiliary circuit. In such examples, the intermediate terminal 152 of the first driver circuit is coupled to the input terminal of the auxiliary circuit, and the output terminal of the auxiliary circuit is coupled to the fourth terminal 122 of the control circuitry 118. In some examples, the value of C1 is selected based on a predetermined gate-to-source capacitance (Cgs) for the transistor M6 and a predetermined gate-to-drain capacitance (Cgd) for the transistor M5.

In the example of FIG. 1, the controller 183 operates to provide control signals EP and EN. In some examples, EP and EN are differential signals. The laser driver circuit 102 operates to: receive a voltage VSET at the first terminal 104; receive EP at the third terminal 106; receive EN at the fourth terminal 107; receive PVDD at the sixth terminal 109; receive VCC at the seventh terminal 110; and provide an output current (IOUT) at the fifth terminal 108 responsive to PVDD, VCC, VSET, the value of the resistor RSET, the size ratio of the transistor M2 relative to the transistor M1, the operations of the current mirror formed by transistors M3 to M5, and control of the transistor M6. In some examples, the values of VSET and the resistor RSET are used to set the value for the current I1 through the transistor M1. The size ratio (α) of the transistor M2 relative to the transistor M1 is used to set a value for the current α*I1 through the transistor M2, where the operational amplifier 114 and the transistors M1 and M2 operate as a current source. In some examples, α has a value of 10. The current α*I1 is mirrored by the transistors M3 to M5. Control of the transistor M6 results in the mirror current being provided as IOUT at fifth terminal 108 of the laser driver circuit 102. In some examples, IOUT has a ratio 500-to-1 relative to α*I1. In some examples, a laser driver circuit 102 may include multiple modules, each module including the circuitry described for the laser driver circuit 102 and providing a separate IOUT. The IOUTs of multiple modules may be combined to provide a drive current for the laser diode LD1. As an example, a laser driver circuit 102 may include 10 modules, where each module provides an IOUT of 500 mA. In this example, the IOUT for each module is combined to provide a driver current (e.g., 5 A) for the laser diode LD1. With the control circuitry 118, the voltage at the control terminals of the transistors M5 and M6 is regulated to reduce overshoot and the settling time for IOUT. Each module of a laser driver circuit may similarly regulate voltage for control terminals of respective target transistors (e.g., similar to the transistors M5 and M6) to reduce overshoot and the settling time for the IOUT of each module.

In some examples, the control circuitry 118 operates to: receive EP at the first terminal 119; receive EN at the second terminal; receive PVDD at the sixth terminal 124; provide a first control voltage at the fifth terminal 123 responsive to EP, EN, the operations of the differential amplifier 128, the operations of the inverters 134 and 140 powered by PVDD, the operations of the LDO 160 to provide the voltage NCAS_B responsive to NCAS and PVDD, the operations of the inverter 146 powered by NCAS_B, and the operations of the first non-overlapping driver circuit 154. In some examples, the level shifter 133 changes the voltage domain from a first voltage domain (e.g., VCC, GND) to a second voltage domain (e.g., PVDD, PGND). In some examples, the control circuitry 118 operates to: receive the current α*I1 at the third terminal 121; provide charge at the fourth terminal 122 of the control circuitry 118 responsive to the current α*I1 and operations of the analog buffer 166; and perform charge cancellation operations at the fourth terminal 122 of the control circuitry 118 responsive to the operations of the auxiliary circuit (e.g., the second non-overlapping driver circuit 178 powered by NCAS_B and the capacitor C1). With the charge cancellation, the size and power consumption of the analog buffer 166 is reduced by 5×.

In the example of FIG. 1, IOUT from the laser driver circuit 102 is used to drive the laser driver LD1, where the diode D1 controls the direction of current flow to the laser diode LD1 and the voltage VLD at the first terminal 174 of the laser diode LD1 is VLD. In some examples, the diode D1 is a free-wheeling diode that conducts when the laser diode LD1 is turned off and prevents the voltage at the fifth terminal 108 of the laser driver circuit 102 from overshooting. The capacitor COUT represents the sum of parasitic capacitance due to pin capacitance and on-chip routing capacitance at the fifth terminal 108. The snubber components (the resistor Rsnub and the capacitor Csnub) reduce overshoot and ringing through the laser diode LD1 and helps with eye-safety and reliability of devices coupled to the fifth terminal 108 of the laser driver circuit 102 The laser diode LD1 provides light pulses to an optical channel responsive to IOUT and the laser driver voltage VLD. The photodiode 192 receives light pulses from an optical channel (e.g., light pulses from the laser diode LD1 or other light sources) at its input 194 and provides corresponding electrical pulses at its output 195. The controller 183 receives the electrical pulses from the photodiode 192 at the first terminal 184. In some examples, the controller 183 operates to process, count, or otherwise analyze such electrical pulses to determine TOF parameters or as data bits. In some examples, the controller 183 may control VSET. In one example, the controller 183 monitors the output from the photodiode 192, which represents the optical power sent by laser diode LD1 to the optical channel. The controller 183 can respond to the amplitude of the pulses of the output from the photodiode 192 to control the VSET (sometimes referred to as a power control loop). The controller 183 may also control the pulse width and/or frequency of the EP and EN pulses.

In some examples, an electronic circuit includes: an output (e.g., the fifth terminal 108 of the laser driver circuit 102); a first transistor (e.g., the transistor M5) having a current path terminal coupled to the output; a second transistor (e.g., the transistor M6) having a current path terminal coupled between the output and the current path terminal of the first transistor; a driver circuit (e.g., the inverters 134, 140, 146, and/or the first non-overlapping driver circuit 154) having an input (e.g., the input 136 of the inverter 134 or the input 156 of the first non-overlapping driver circuit 154) and an output (e.g., the output 158 of the first non-overlapping driver circuit 154), the output of the driver circuit coupled to a control terminal of the second transistor; an analog buffer (e.g., the analog buffer 166) having an output (e.g., the output 172) coupled to a control terminal of the first transistor; and an auxiliary circuit (e.g., the second non-overlapping driver circuit 178 and the capacitor C1) configured to apply charge cancellation to the control terminal of the first transistor responsive to a signal (e.g., the output of the differential amplifier 128) at the input of the first driver circuit.

In some examples, the auxiliary circuit includes a capacitor (e.g., the capacitor C1) coupled to the control terminal of the first transistor. In some examples, the driver circuit is a first driver circuit and the auxiliary circuit includes a non-overlapping driver circuit (e.g., the second non-overlapping driver circuit 178) having an input (e.g., the input 180) and an output (e.g., the output 182). The input of the first non-overlapping driver circuit is coupled to the first driver circuit. The output of the non-overlapping driver circuit is coupled to the capacitor.

In some examples, the first driver circuit includes an inverter (e.g., the inverter 146) having an output (e.g., the output 150) coupled to the control terminal of the second transistor and the input of the non-overlapping driver circuit. In some examples, the driver circuit includes a first plurality of inverters (e.g., the inverters 134, 140, and 146) coupled in series, the first plurality of inverters having an output terminal (e.g., the output 150) coupled to the control terminal of the second transistor.

In some examples, the electronic circuit includes a third transistor (e.g., the transistor M4) having a control terminal and a current path terminal. The control terminal of the third transistor is coupled to the control terminal of the first transistor. The current path terminal of the third transistor is coupled to the control terminal of the third transistor. In some examples the electronic circuit includes a current source (e.g., the operational amplifier 114 and the transistors M1 and M2) coupled to the current path terminal of the third transistor. In some examples, the electronic circuit includes a fourth transistor (e.g., the transistor M3) having a first current path terminal and a second current path terminal. The first current path terminal of the fourth transistor is coupled to the current source and to the control terminal of the third transistor. The second current path terminal of the fourth transistor is coupled to the current path terminal of the third transistor.

In some examples, the electronic circuit is configured to: receive a first supply voltage (e.g., PVDD herein); receive a first signal (e.g., EP herein); receive a second signal (e.g., EN herein); determine a difference result between the first signal and the second signal; and control a first part of the driver circuit (e.g., the inverters 134, 140, 146) responsive to the first supply voltage and the difference result. In some examples, the electronic circuit is configured to: generate a second supply voltage (e.g., NCAS_B herein) responsive to the first supply voltage; and control a second part of the driver circuit (e.g., the first non-overlapping driver circuit 154) responsive to the output of the first part of the driver circuit and the second supply voltage. In some examples, the electronic circuit is configured to: buffer the difference result (e.g., using inverters 134, 140, and 146) responsive to the first supply voltage, resulting in a buffered difference result; and control the second part of the first driver circuit responsive to the buffered difference result and the second supply voltage.

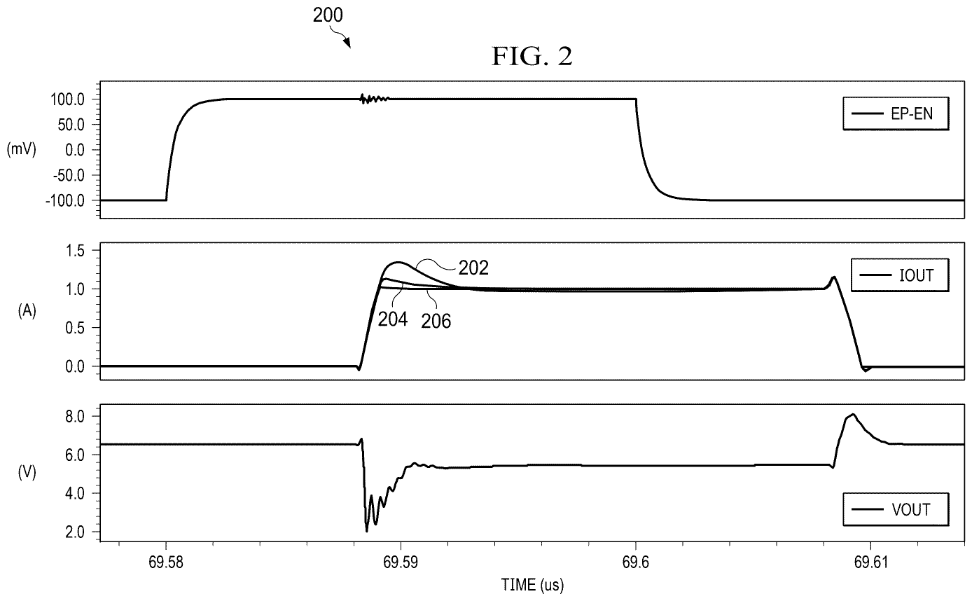

In the example of FIG. 1, NCAS_B is selected to be an optimal voltage to drive the transistor M6. In some examples, the voltage at the control terminal of the transistor M6 goes from 0 v to NCAS_B when the transistor M6 is to be turned ON. During this event, VOUT falls (see FIG. 2). With the NCAS_B voltage, the transistor M6 does not enter into the linear region when the current is rising. If the transistor M6 were to operate in the linear region, the gate-to-drain capacitance (Cgd) of the transistor M6 increases, which: 1) reduces the rise time of IOUT current (due to the Cgd preventing some current from going to IOUT when VOUT is falling; and 2), adds to the IOUT current (due to inrush current through Cgd) resulting in overshoot.

In some examples, an electronic circuit includes: an output (e.g., the fifth terminal 108 of the laser driver circuit 102); a first transistor (e.g., the transistor M5) having a current path terminal coupled to the output; a second transistor (e.g., the transistor M6) having a current path terminal coupled between the output and the current path terminal of the first transistor; a buffer chain (e.g., the inverters 134, 140, and 146) having an input and an output, the output of the buffer chain coupled to a control terminal of the second transistor; a non-overlapping driver circuit (e.g., the second non-overlapping driver circuit 178) having an input and an output, the input of the non-overlapping driver circuit coupled to the output of the buffer chain; and a capacitor (e.g., the capacitor C1) coupled between the output of the non-overlapping driver circuit and the control terminal of the first transistor.

In some examples, the electronic circuit includes: a third transistor (e.g., the transistor M4) having a control terminal and a current path terminal, the control terminal of the third transistor coupled to the control terminal of the first transistor, and the current path terminal of the third transistor coupled to the control terminal of the third transistor; a (e.g., the operational amplifier 114 and the transistors M1 and M2) coupled to the current path terminal of the third transistor; and a fourth transistor (e.g., the transistor M3) having a first current path terminal and a second current path terminal, the first current path terminal of the fourth transistor coupled to the current source and to the control terminal of the third transistor, and the second current path terminal of the fourth transistor coupled to the current path terminal of the third transistor. In some examples, the fourth transistor (e.g., the transistor M3) is a similar type as the second transistor (e.g., the transistor M6) and is used for cascading the third transistor (e.g., the transistor M4) to improve current mirror accuracy.

In some examples, the electronic circuit includes an LDO (e.g., the LDO 160) having a power terminal (e.g., the power terminal 163) and an output (e.g., the second output 164). The power terminal of the LDO is coupled to a first supply voltage terminal (e.g., a PVDD terminal such as the sixth terminal 109 of the laser driver circuit 102). The output of the LDO is coupled to a power terminal (e.g., the power terminals 181) of the non-overlapping driver circuit.

In some examples, the buffer chain includes a plurality of inverters in series (e.g., the inverter 134, 140, and 146), each of the plurality of inverters having a power terminal coupled to a first supply voltage terminal (e.g., a PVDD terminal) and the electronic circuit includes a differential amplifier (e.g., the differential amplifier 128) having an output (e.g., the output 132) coupled to the input of the buffer chain.

In some examples, the electronic circuit includes: an analog buffer (e.g., the analog buffer 166) having a power terminal (e.g., the power terminal 170) and an output (e.g., the output 172), the power terminal of the analog buffer coupled to the first supply voltage terminal; the output of the analog buffer coupled to the control terminal of the first transistor. In some examples, the capacitor (e.g., the capacitor C1) is a first capacitor, and the electronic circuit includes a second capacitor (e.g., the capacitor C2) having a first terminal and a second terminal. The first terminal of the second capacitor is coupled to the control terminal of the first transistor. The second terminal of the capacitor is coupled to a ground terminal.

In some examples, a system (e.g., the system 100 in FIG. 1) includes: a controller (e.g., the controller 183); and a laser driver (e.g., the laser driver circuit 102) coupled to the controller. The laser driver includes: a first transistor (e.g., the transistor M5) and a second transistor (e.g., the transistor M6), the first transistor having a control terminal, and the second transistor having a control terminal; and control circuitry (e.g., the control circuitry 118) having a first output terminal (e.g., the fourth terminal 122) and a second output terminal (e.g., the fifth terminal 123). The first output terminal coupled to the control terminal of the first transistor. The second output terminal is coupled to the control terminal of the second transistor. In such examples, the control circuitry is configured to: provide a first charge to the first output terminal; provide a second charge to the second output terminal based on an output (e.g., EP and EN herein) of the controller; and while providing the first charge to the first output terminal and the second charge at the second output terminal, apply a charge cancellation at the first output terminal responsive to the second charge at the second output terminal.

In some examples, the system includes a photodiode (e.g., the photodiode 192) coupled to the controller, where the controller is configured to determine a TOF value based on an output of the photodiode and the output of the controller. In some examples, the laser driver has an output terminal (e.g., the fifth terminal 108), the first transistor has a first current path terminal and a second current path terminal, the second transistor has a first current path terminal and a second current path terminal. In such examples, the first current path terminal of the second transistor is coupled to the output terminal of the laser driver. The second current path terminal of the second transistor is coupled to the first current path terminal of the first transistor. The second current path terminal of the first transistor is coupled to a ground terminal, and the system includes a laser diode (e.g., the laser diode LD1) having a first terminal (e.g., the first terminal 174 in FIG. 1) coupled to the output terminal of the laser driver. In some examples, the laser driver is part of an IC with the first transistor, the second transistor, and the control circuitry, and the controller and the laser diode are separate from the IC.

In some examples, the control circuitry includes: an inverter (e.g., the inverter 146) having an output (e.g., the output 150); a first non-overlapping driver circuit (e.g., the first non-overlapping driver circuit 154) having an input (e.g., the input 156) coupled to the output of the inverter; a second non-overlapping driver circuit (e.g., the second non-overlapping driver circuit 178) having an input (e.g., the input 180) and an output (e.g., the output 182), the input of the second non-overlapping driver circuit coupled to the output of the inverter and the input of the first non-overlapping driver circuit; and a capacitor (e.g., the capacitor C1) having a first terminal and a second terminal, the first terminal of the capacitor coupled to the output of the second non-overlapping driver circuit, and the second terminal of the capacitor coupled to the first output terminal of the control circuit.

In some examples, the first non-overlapping driver circuit has an input and power terminal, the second non-overlapping driver circuit has an input and a power terminal, the controller has a first terminal and a second terminal, and the control circuitry includes: an LDO having a power terminal and an output, the power terminal of the LDO coupled to a first supply voltage terminal (e.g., a PVDD terminal), the output of the LDO coupled to the power terminals of the first and second non-overlapping driver circuits. In such examples, the control circuitry also includes: a differential amplifier (e.g., the differential amplifier 128) having a first input, a second input, and an output, the first input of the differential amplifier coupled to the first terminal of the controller, and the second input of the differential amplifier coupled to the second terminal of the controller; a first inverter (e.g., the inverter 134) having an input, a power terminal, and an output, the input of the first inverter coupled to the output of the differential amplifier; a second inverter (e.g., the inverter 140) having an input, a power terminal, and an output, the input of the second inverter coupled to the output of the first inverter; and a third inverter (e.g., the inverter 146) having an input, a power terminal, and an output. The input of the third inverter is coupled to the output of the second inverter. The output of the third inverter is coupled to the inputs of the first and second non-overlapping driver circuits. The power terminals of the first, second, and third inverters are coupled to the first supply voltage terminal.

FIG. 2 is a graph 200 showing signals related to a laser driver circuit (e.g., the laser driver circuit 102 in FIG. 1), in accordance to an embodiment of the present disclosure. In the graph 200 of FIG. 2, the signals represented include EP-EN, IOUT waveforms 202, 204, 206, and output voltage (VOUT). EP-EN is the difference between EP and EN. In graph 200, IOUT is the post-snubber current going into the inductor L1 and the laser diode LD1 rather than the current at the fifth terminal 108 of the laser driver circuit 102. VOUT is the voltage at the fifth terminal 108 of the laser driver circuit 102. In the graph 200, EP-EN is a control signal that determines the duration of an IOUT pulse (i.e., the IOUT pulse is a delayed pulse with the approximately same duration as EP-EN being high). In different examples, IOUT may be used to drive a laser for TOF analysis, communications via an optical channel, or other operations. In the example of FIG. 2, EP-EN transitions from −100 mV to 100 mV and back to −100 mV. In other examples, the particular voltages used may vary. When EP-EN is positive, the laser driver circuit operates to: provide a first gate voltage to the control terminal of the transistor M6, resulting in IOUT increasing from 0 to above 1 A and then settling. The IOUT waveform 202 represents IOUT without charge cancellation and buffering for the second gate voltage. As shown, the IOUT waveform 202 has a large overshoot (e.g., 26%) and longer settling time compared to the IOUT waveforms 204 and 206. The IOUT waveform 204 represents IOUT with buffering and without charge cancellation for the second gate voltage. Compared to the IOUT waveform 202, the IOUT waveform 204 has a reduced overshoot (e.g., 11%) and settling time. Without the charge cancellation, the size and power consumption of the analog buffer 166 increases by 5×. The IOUT waveform 206 represents IOUT with buffering and with charge cancellation for the second gate voltage. Compared to the IOUT waveforms 202 and 204, the IOUT waveform 206 has a reduced overshoot (e.g., 3.5%) and settling time (e.g., a 40% reduction compared to the IOUT waveform 204). For all of the IOUT waveforms 202, 204, 206, VOUT will drop from an initial value (e.g., 6.5V in FIG. 2) as IOUT increases, settle to second value (e.g., 5.5V) when IOUT is high, and return to the initial value once IOUT returns to 0.

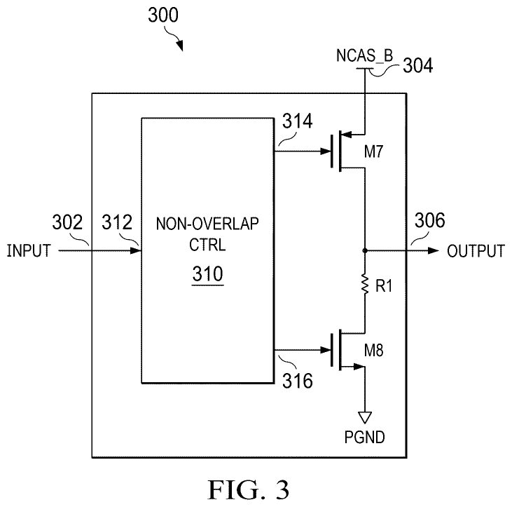

FIG. 3 is a diagram of a non-overlapping driver circuit 300, in accordance to an embodiment of the present disclosure. The non-overlapping driver circuit 300 in FIG. 3 is an example of the first non-overlapping driver circuit 154 or the second non-overlapping driver circuit 178. In the example of FIG. 3, the non-overlapping driver circuit 300 has an input 302, a power terminal 304, and an output 306. The input 302 is an example of the input 156 of the first non-overlapping driver circuit 154 in FIG. 1 or the input 180 of the second non-overlapping driver circuit 178 in FIG. 1. The power terminal 304 is an example of the power terminal 157 of the first non-overlapping driver circuit 154 in FIG. 1 or the power terminal 181 of the second non-overlapping driver circuit 178 in FIG. 1. The output 306 is an example of the output 158 of the first non-overlapping driver circuit 154 in FIG. 1 or the output 182 of the second non-overlapping driver circuit 178 in FIG. 1.

In some examples, the non-overlapping driver circuit 300 includes a non-overlap controller 310, transistors M7 and M8, and a resistor R1. The non-overlap controller 310 has a first terminal 312, a second terminal 314, and a third terminal 316. Each of the transistors M7 to M8 has a respective first current path terminal (e.g., a drain terminal), a second current path terminal (e.g., a source terminal), and a control terminal (e.g., a gate terminal). In the example of FIG. 3, the transistor M7 is a PMOS transistor and the transistor M8 is an NMOS transistor. The resistor R1 has a first terminal and a second terminal.

In the example of FIG. 3, the first terminal 312 of the non-overlap controller 310 is coupled to the input 302 of the non-overlapping driver circuit 300. The second terminal 314 of the non-overlap controller 310 is coupled to the control terminal of the transistor M7. In some examples, the non-overlap controller 310 is powered by PVDD. The third terminal 316 of the non-overlap controller 310 is coupled to the control terminal of the transistor M8. The second terminal of the transistor M7 is coupled to the power terminal 304 of the non-overlapping driver circuit 300. The first terminal of the transistor M7 is coupled to the first terminal of the resistor R1 and the output 306 of the non-overlapping driver circuit 300. The second terminal of the resistor R1 is coupled to the first terminal of the transistor M8. The second terminal of the transistor M8 is coupled to ground or a ground terminal.

In some examples, the non-overlapping driver circuit 300 operates to: receive an input signal (e.g., a buffered signal from the inverter 146) at the input 302; receive a power supply voltage (e.g., NCAS_B) at the power terminal 304; provide the power supply voltage or a ground voltage at the output 306 responsive to the input signal and the operations of the non-overlap controller 310. With the non-overlap controller 310, the transistors M7 and M8 are controlled in a non-overlapping manner to avoid shoot through current. The non-overlap controller 310 may be implemented in any way known in the art. The resistor R1 is used to control the fall time at a target terminal (e.g., the control terminal of the transistor M6).

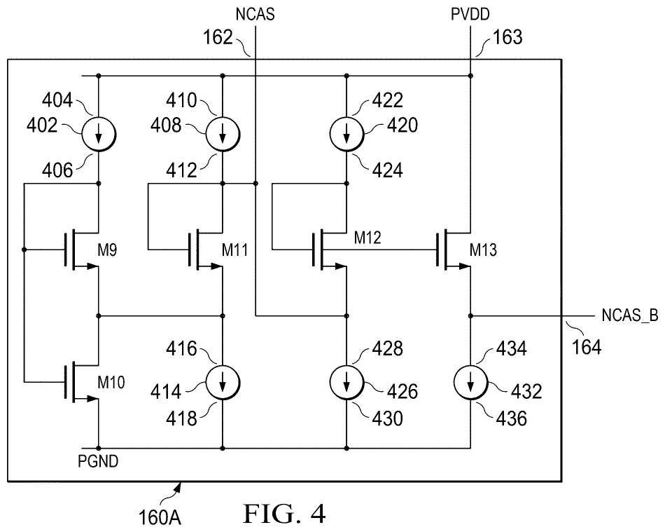

FIG. 4 is a schematic diagram of an LDO, in accordance to an embodiment of the present disclosure. The LDO 160A in FIG. 4 is an example of the LDO 160 in FIG. 1. In the example of FIG. 4, the LDO 160A has the first output 162, the power terminal 163, and the second output 164 described in FIG. 1. In some examples, the LDO 160A includes a first current source 402, a second current source 408, a third current source 414, a fourth current source 420, a fifth current source 426, a sixth current source 432, and transistor M9 to M13 in the arrangement shown.

The first current source 402 has a first terminal 404 and a second terminal 406. The second current source 408 has a first terminal 410 and a second terminal 412. The third current source 414 has a first terminal 416 and a second terminal 418. The fourth current source 420 has a first terminal 422 and a second terminal 424. The fifth current source 426 has a first terminal 428 and a second terminal 430. The sixth current source 432 has a first terminal 434 and a second terminal 436. Each of the transistors M9 to M13 has a respective first current path terminal (e.g., a drain terminal), a second current path terminal (e.g., a source terminal), and a control terminal (e.g., a gate terminal). In the example of FIG. 4, the transistors M9 to M13 are NMOS transistors.

In example of FIG. 4, the first output 162 of the LDO 160A is coupled to the second terminal 412 of the second current source 408, the first current path terminal of the transistor M11, the control terminal of the transistor M11, the second current path terminal of the transistor M12, and the first terminal 428 of the fifth current source 426. The power terminal 163 of the LDO 160A is coupled to the first terminal 404 of the first current source 402, the first terminal 410 of the second current source 408, the first terminal 422 of the fourth current source 420, and the first current path terminal of the transistor M13.

The second terminal 406 of the first current source 402 is coupled to the first current path terminal of the transistor M9 and the control terminals of the transistors M9 and M10. The second current path terminal of the transistor M9 is coupled to the first current path terminal of the transistor M10, the second current path terminal of the transistor M11, and the first terminal 416 of the third current source 414. The second current path terminal of the transistor M10 is coupled to ground or a ground terminal. The second terminal 418 of the third current source 414 is coupled to ground or a ground terminal. The second terminal 424 of the fourth current source 420 is coupled to the first current path terminal and the control terminal of the transistor M12. The second terminal 430 of the fifth current source 426 is coupled to ground or a ground terminal. The second current path terminal of the transistor M13 is coupled to the first terminal 434 of the sixth current source 432 and the second output 164 of the LDO 160A.

In some examples, the transistors M9 and M10 are low-voltage (e.g., below 5V) transistor matching the transistor M5. The transistor M11 is a high-voltage (e.g., 18V) transistor matching the transistor M6. In some examples, the transistor M13 is larger than (e.g., 20×) the transistor M12. In some examples, the second output 164 is coupled to an external capacitor (e.g., Cext in FIG. 1). In one example, the capacitor Cext has a value of 1 uF.

In some examples, the LDO 160A operates to: receive PVDD at the power terminal 163; provide NCAS at the first output 162 responsive to PVDD and the operations of the first current source 402, the second current source 408 and the transistors M9, M10, and M11; and provide NCAS_B at the second output 164 responsive to NCAS, PVDD, and buffering operations the fourth current source 420, the fifth current source 426, the sixth current source 432, and the transistors M12 and M13.

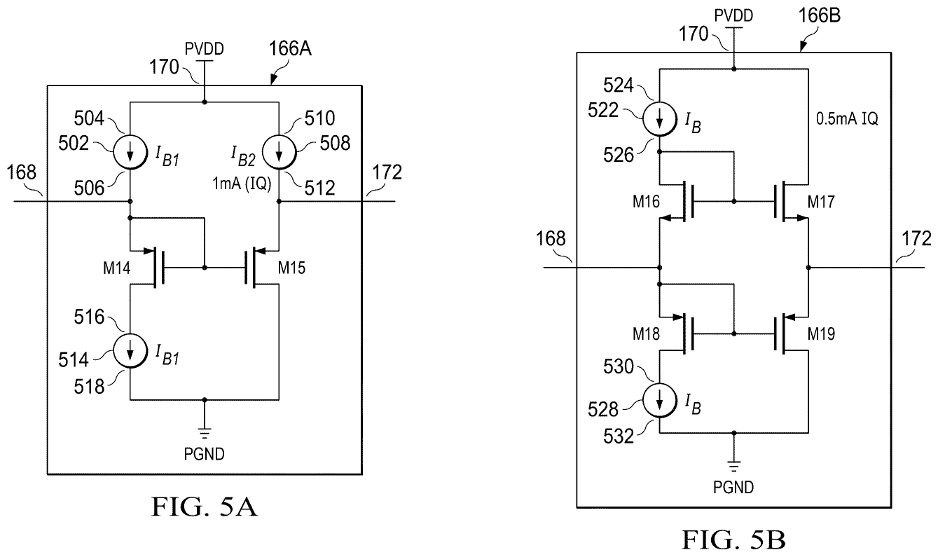

FIG. 5A is a schematic diagram of an analog buffer 166A, in accordance to an embodiment of the present disclosure. The analog buffer 166A in FIG. 5A is an example of the analog buffer 166 in FIG. 1. In the example of FIG. 5A, the analog buffer 166A includes the input 168, the power terminal 170, and the output 172 described in FIG. 1. As shown, the analog buffer 166A includes a first bias current (I_{B1}) source 502, a bias current (I_{B2}) source 508, a second I_{B1} source 514, and transistors M14 and M15 in the arrangement shown.

The first I_{B1} source 502 has a first terminal 504 and a second terminal 506. The I_{B2} source 508 has a first terminal 510 and a second terminal 512. The second I_{B1} source 514 has a first terminal 516 and a second terminal 518. In some examples, each of the first I_{B1} source 502, the I_{B2} source 508, and the second I_{B1} source 514 operates to provide a respective target current (e.g., I_{B1}=50 uA, I_{B2}=1 mA quiescent current). Each of the transistors M14 and M15 has a respective first current path terminal (e.g., a drain terminal), a second current path terminal (e.g., a source terminal), and a control terminal (e.g., a gate terminal). In the example of FIG. 5A, the transistors M14 and M15 are PMOS transistors and the transistor M15 is larger than M14 (e.g., if the transistor M14 has size x, the transistor M20 may have size 20×).

In the example of FIG. 5A, the input 168 of the analog buffer 166A is coupled to the second terminal 506 of the first I_{B1} source 502, the second current path terminal of the transistor M14, and the control terminal of the transistors M14 and M15. The first terminals of the first I_{B1} source 502 and the I_{B2} source 508 are coupled to the power terminal 170. The first current path terminal of the transistor M14 is coupled to the first terminal 516 of the second I_{B1} source 514. The second terminal 518 of the second I_{B1} source 514 is coupled to ground or a ground terminal. The second terminal 512 of the I_{B2} source 508 is coupled to the second current path terminal of the transistor M15 and the output 172 of the analog buffer 166A. The first current path terminal of the transistor M15 is coupled to ground or a ground terminal. With the analog buffer 166A, the signal at input 168 is buffered responsive to PVDD, and the buffer signal is provided at the output 172.

FIG. 5B is a schematic diagram of another analog buffer 166B, in accordance to an embodiment of the present disclosure. The analog buffer 166B in FIG. 5B is an example of the analog buffer 166 in FIG. 1. In the example of FIG. 5B, the analog buffer 166B includes the input 168, the power terminal 170, and the output 172 described in FIG. 1. As shown, the analog buffer 166B includes a first bias current (I_{B}) source 522, a second I_{B} source 528, and transistors M16 to M19 in the arrangement shown. In some examples, each of the first I_{B} source 522 and the second I_{B} source 528 operates to provide a target current (e.g., a 0.5 mA quiescent current).

The first I_{B} source 522 has a first terminal 524 and a second terminal 526. The second I_{B} source 528 has a first terminal 530 and a second terminal 532. The second I_{B} source 528 has a first terminal 530 and a second terminal 532. Each of the transistors M16 to M19 has a respective first current path terminal (e.g., a drain terminal), a second current path terminal (e.g., a source terminal), and a control terminal (e.g., a gate terminal). In the example of FIG. 5B, the transistors M16 and M17 are NMOS transistors, while the transistors M18 and M19 are PMOS transistors.

In the example of FIG. 5B, the input 168 of the analog buffer 166B is coupled to the second current path terminals of the transistors M16 and M18, and the control terminals of the transistors M18 and M19. The power terminal 170 of the analog buffer 166B is coupled to the first terminal 524 of the first I_{B} source 522 and the first current path terminal of the transistor M17. The second terminal 526 of the first I_{B} source 522 is coupled to the first current path terminal of the transistor M16 and the control terminals of the transistors M16 and M17. The first current path terminal of the transistor M18 is coupled to the first terminal 530 of the second I_{B} source 528. The second terminal 532 of the second I_{B} source 528 is coupled to ground or a ground terminal. The second current path terminals of the transistors M17 and M19 are coupled to the output 172. The first current path terminal of the transistor M19 is coupled to ground or a ground terminal. With the analog buffer 166B, the signal at input 168 is buffered responsive to PVDD, and the buffered signal is provided at the output 172. With charge cancellation at the control terminal of the transistor M5 (at the output 172 of the analog buffer 166A in FIG. 5A, or at the output 172 of the analog buffer 166B in FIG. 5B), the size of the analog buffer 166A or the analog buffer 166B can be smaller (e.g., a reduction of 5× in size and power consumption) compared to a laser driver without charge cancellation.

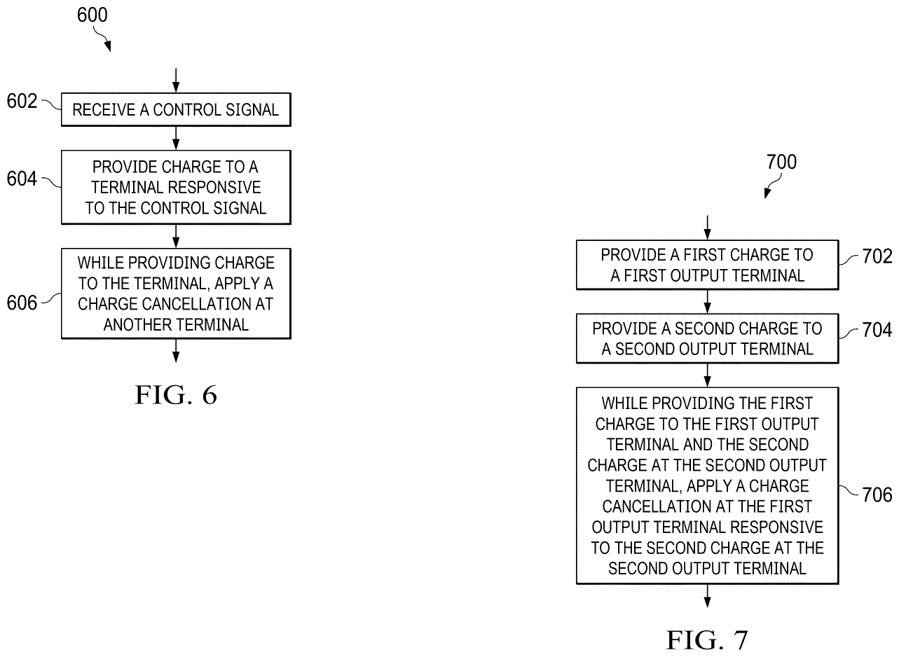

FIG. 6 is a flowchart of a laser driver method 600, in accordance to an embodiment of the present disclosure. The laser driver method 600 may be performed, for example, by the laser driver circuit 102 in FIG. 1. As shown, the laser driver method 600 includes receiving a control signal (e.g., EP-EN) at block 602. At block 604, charge is provided to a terminal (e.g., the fifth terminal 123 of the control circuitry 118 in FIG. 1) responsive to the control signal. At block 606, while providing charge to the terminal, a charge cancellation is applied at another terminal (e.g., the fourth terminal 122 of the control circuitry 118 in FIG. 1).

FIG. 7 is a flowchart of a laser driver method 700, in accordance to an embodiment of the present disclosure. The laser driver method 700 may be performed, for example, by the laser driver circuit 102 in FIG. 1. As shown, the laser driver method 700 includes providing a first charge (e.g., the gate voltage for the control terminal of the transistor M5) to a first output terminal (e.g., the fourth terminal 122 of the control circuitry 118 in FIG. 1) at block 702. At block 704, a second charge (e.g., the gate voltage for the control terminal of the transistor M6) is provided to a second output terminal (e.g., the fifth terminal 123 of the control circuitry 118 in FIG. 1). At block 706, while providing the first charge to the first output terminal and the second charge to the second output terminal, a charge cancellation is applied at the first output terminal responsive to second charge at the second output terminal. With the laser driver methods 600 and 700, IOUT overshoot and settling time is reduced, which enables fast and accurate laser driver operations.

Example embodiments of the present disclosure are summarized here. Other embodiments can also be understood from the entirety of the specification and the claims filed herein.

Example 1. An electronic circuit including: an output terminal; a first transistor having a current path terminal coupled to the output terminal; a second transistor having a current path terminal coupled between the output and the current path terminal of the first transistor; a driver circuit having an input and an output, the output of the driver circuit coupled to a control terminal of the second transistor; an analog buffer having an output coupled to a control terminal of the first transistor; and an auxiliary circuit configured to apply charge cancellation to the control terminal of the first transistor responsive to a signal at the input of the driver circuit.

Example 2. The electronic circuit of example 1, where the auxiliary circuit includes a capacitor coupled to the control terminal of the first transistor.

Example 3. The electronic circuit of one of examples 1 or 2, where driver circuit is a first driver circuit, the auxiliary circuit includes a non-overlapping driver circuit having an input and an output, the input of the non-overlapping driver circuit coupled to the first driver circuit, and the output of the first non-overlapping driver circuit coupled to the capacitor.

Example 4. The electronic circuit of one of examples 1 to 3, where the first driver circuit includes an inverter having an output coupled to the control terminal of the second transistor and the input of the non-overlapping driver circuit.

Example 5. The electronic circuit of one of examples 1 to 4, where the driver circuit includes a plurality of inverters coupled in series, the plurality of inverters having an output coupled to the control terminal of the second transistor.

Example 6. The electronic circuit of one of examples 1 to 5, further including a third transistor having a control terminal and a current path terminal, the control terminal of the third transistor coupled to the control terminal of the first transistor, and the current path terminal of the third transistor coupled to the control terminal of the third transistor.

Example 7. The electronic circuit of one of examples 1 to 6, further including a current source coupled to the current path terminal of the third transistor.

Example 8. The electronic circuit of one of examples 1 to 7, further including a fourth transistor having a first current path terminal and a second current path terminal, the first current path terminal of the fourth transistor coupled to the current source and to the control terminal of the third transistor, and the second current path terminal of the fourth transistor coupled to the current path terminal of the third transistor.

Example 9. The electronic circuit of one of examples 1 to 8, where the electronic circuit is configured to: receive a first supply voltage; receive a first signal; receive a second signal; determine a difference result between the first signal and the second signal; and control a first part of the driver circuit responsive to the first supply voltage and the difference result.

Example 10. The electronic circuit of one of examples 1 to 9, where the electronic circuit is configured to: generate a second supply voltage responsive to the first supply voltage; and control a second part of the driver circuit responsive to the second supply voltage.

Example 11. The electronic circuit of one of examples 1 to 10, where the electronic circuit is configured to: buffer the difference result responsive to the first supply voltage, resulting in a buffered difference result; and control the second part of the driver circuit responsive to the buffered difference result and the second supply voltage.

Example 12. An electronic circuit including: an output terminal; a first transistor having a current path terminal coupled to the output terminal; a second transistor having a current path terminal coupled between the output terminal and the current path terminal of the first transistor; a buffer chain having an input and an output, the output of the buffer chain coupled to a control terminal of the second transistor; a non-overlapping driver circuit having an input and an output, the input of the non-overlapping driver circuit coupled to the output of the buffer chain; and a capacitor coupled between the output of the non-overlapping driver circuit and the control terminal of the first transistor.

Example 13. The electronic circuit of example 12, further including: a third transistor having a control terminal and a current path terminal, the control terminal of the third transistor coupled to the control terminal of the first transistor, and the current path terminal of the third transistor coupled to the control terminal of the third transistor; a current source coupled to the current path terminal of the third transistor; and a fourth transistor having a first current path terminal and a second current path terminal, the first current path terminal of the fourth transistor coupled to the current source and to the control terminal of the third transistor, and the second current path terminal of the fourth transistor coupled to the current path terminal of the third transistor.

Example 14. The electronic circuit of one of examples 12 or 13, further including a low-dropout regulator (LDO) having a power terminal and an output, the power terminal of the LDO coupled to a first supply voltage terminal, and the output of the LDO coupled to a power terminal of the non-overlapping driver circuit.

Example 15. The electronic circuit of one of examples 12 to 14, where the buffer chain includes a plurality of inverters in series, each of the plurality of inverters having a power terminal coupled to a first supply voltage terminal and the electronic circuit further includes a differential amplifier having an output coupled to the input of the buffer chain.

Example 16. The electronic circuit of one of examples 12 to 15, further including an analog buffer having a power terminal and an output, the power terminal of the analog buffer coupled to the first supply voltage terminal, and the output of the analog buffer coupled to the control terminal of the first transistor.

Example 17. The electronic circuit of one of examples 12 to 16, where the capacitor is a first capacitor, and the electronic circuit further includes a second capacitor having a first terminal and a second terminal, the first terminal of the second capacitor coupled to the control terminal of the first transistor, and the second terminal of the capacitor coupled to a ground terminal.

Example 18. A system including: a controller; and a laser driver coupled to the controller, the laser driver including: a first transistor and a second transistor, the first transistor having a control terminal, and the second transistor having a control terminal; and control circuitry having a first output terminal and a second output terminal, the first output terminal coupled to control terminal of the first transistor, and the second output terminal coupled to the control terminal of the second transistor, where the control circuitry is configured to: provide a first charge to the first output terminal; provide a second charge to the second output terminal based on an output of the controller; and while providing the first charge to the first output terminal and the second charge at the second output terminal, apply a charge cancellation at the first output terminal responsive to the second charge at the second output terminal.

Example 19. The system of example 18, further including a photodiode coupled to the controller, where the controller is configured to determine a time-of-flight value based on an output of the photodiode and the output of the controller.

Example 20. The system of one of examples 18 or 19, where the laser driver has an output terminal, the first transistor has a first current path terminal and a second current path terminal, the second transistor has a first current path terminal and a second current path terminal, the first current path terminal of the second transistor coupled to the output terminal of the laser driver, the second current path terminal of the second transistor coupled to the first current path terminal of the first transistor, the second current path terminal of the first transistor coupled to a ground terminal, and the system further includes a laser diode having a first terminal coupled to the output terminal of the laser driver.

Example 21. The system of one of examples 18 to 20, where the laser driver is part of an integrated circuit (IC) with the first transistor, the second transistor and the control circuitry, and the controller and the laser diode are separate from the IC.

Example 22. The system of one of examples 18 to 21, where the control circuitry includes: an inverter having an output; a first non-overlapping driver circuit having an output coupled to the second output terminal of the control circuitry; a second non-overlapping driver circuit having an output; and a capacitor having a first terminal and a second terminal, the first terminal of the capacitor coupled to the output of the second non-overlapping driver circuit, and the second terminal of the capacitor coupled to the first output terminal of the control circuit.

Example 23. The system of one of examples 18 to 22, where the first non-overlapping driver circuit has an input and power terminal, the second non-overlapping driver circuit has an input and a power terminal, the controller has a first terminal and a second terminal, and the control circuitry includes: a low-dropout regulator (LDO) having a power terminal and an output, the power terminal of the LDO coupled to a first supply voltage terminal, the output of the LDO coupled to the power terminals of the first and second non-overlapping driver circuits; a differential amplifier having a first input, a second input, and an output, the first input of the differential amplifier coupled to the first terminal of the controller, and the second input of the differential amplifier coupled to the second terminal of the controller; a first inverter having an input, a power terminal, and an output, the input of the first inverter coupled to the output of the differential amplifier; a second inverter having an input, a power terminal, and an output, the input of the second inverter coupled to the output of the first inverter; and a third inverter having an input, a power terminal, and an output, the input of the third inverter coupled to the output of the second inverter, the output of the third inverter coupled to the inputs of the first and second non-overlapping driver circuits, and the power terminals of the first, second, and third inverters coupled to the first supply voltage terminal.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs). For different transistor types, the variable gain of a variable gain current mirror may vary for the same output current and gain resistor value.

Circuits described herein may be reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, unless otherwise stated, “about,” “approximately” or “substantially” preceding a parameter means being within +/−10 percent of that parameter or, if the parameter is zero, a reasonable range of values around zero.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An electronic circuit comprising:
an output terminal;
a first transistor having a current path terminal coupled to the output terminal;
a second transistor having a current path terminal coupled between the output and the current path terminal of the first transistor;
a driver circuit having an input and an output, the output of the driver circuit coupled to a control terminal of the second transistor;
an analog buffer having an output coupled to a control terminal of the first transistor; and
an auxiliary circuit configured to apply charge cancellation to the control terminal of the first transistor responsive to a signal at the input of the driver circuit.

2. The electronic circuit of claim 1, wherein the auxiliary circuit comprises a capacitor coupled to the control terminal of the first transistor.

3. The electronic circuit of claim 2, wherein driver circuit is a first driver circuit, the auxiliary circuit comprises a non-overlapping driver circuit having an input and an output, the input of the non-overlapping driver circuit coupled to the first driver circuit, and the output of the first non-overlapping driver circuit coupled to the capacitor.

4. The electronic circuit of claim 3, wherein the first driver circuit comprises an inverter having an output coupled to the control terminal of the second transistor and the input of the non-overlapping driver circuit.

5. The electronic circuit of claim 1, wherein the driver circuit comprises a plurality of inverters coupled in series, the plurality of inverters having an output coupled to the control terminal of the second transistor.

6. The electronic circuit of claim 1, further comprising a third transistor having a control terminal and a current path terminal, the control terminal of the third transistor coupled to the control terminal of the first transistor, and the current path terminal of the third transistor coupled to the control terminal of the third transistor.

7. The electronic circuit of claim 6, further comprising a current source coupled to the current path terminal of the third transistor.

8. The electronic circuit of claim 7, further comprising a fourth transistor having a first current path terminal and a second current path terminal, the first current path terminal of the fourth transistor coupled to the current source and to the control terminal of the third transistor, and the second current path terminal of the fourth transistor coupled to the current path terminal of the third transistor.

9. The electronic circuit of claim 1, wherein the electronic circuit is configured to:
receive a first supply voltage;
receive a first signal;
receive a second signal;
determine a difference result between the first signal and the second signal; and
control a first part of the driver circuit responsive to the first supply voltage and the difference result.

10. The electronic circuit of claim 9, wherein the electronic circuit is configured to:
generate a second supply voltage responsive to the first supply voltage; and
control a second part of the driver circuit responsive to the second supply voltage.

11. The electronic circuit of claim 10, wherein the electronic circuit is configured to:
buffer the difference result responsive to the first supply voltage, resulting in a buffered difference result; and
control the second part of the driver circuit responsive to the buffered difference result and the second supply voltage.

12. An electronic circuit comprising:
an output terminal;
a first transistor having a current path terminal coupled to the output terminal;
a second transistor having a current path terminal coupled between the output terminal and the current path terminal of the first transistor;
a buffer chain having an input and an output, the output of the buffer chain coupled to a control terminal of the second transistor;
a non-overlapping driver circuit having an input and an output, the input of the non-overlapping driver circuit coupled to the output of the buffer chain; and
a capacitor coupled between the output of the non-overlapping driver circuit and the control terminal of the first transistor.

13. The electronic circuit of claim 12, further comprising:
a third transistor having a control terminal and a current path terminal, the control terminal of the third transistor coupled to the control terminal of the first transistor, and the current path terminal of the third transistor coupled to the control terminal of the third transistor;
a current source coupled to the current path terminal of the third transistor; and
a fourth transistor having a first current path terminal and a second current path terminal, the first current path terminal of the fourth transistor coupled to the current source and to the control terminal of the third transistor, and the second current path terminal of the fourth transistor coupled to the current path terminal of the third transistor.

14. The electronic circuit of claim 12, further comprising a low-dropout regulator (LDO) having a power terminal and an output, the power terminal of the LDO coupled to a first supply voltage terminal, and the output of the LDO coupled to a power terminal of the non-overlapping driver circuit.

15. The electronic circuit of claim 12, wherein the buffer chain includes a plurality of inverters in series, each of the plurality of inverters having a power terminal coupled to a first supply voltage terminal and the electronic circuit further comprises a differential amplifier having an output coupled to the input of the buffer chain.

16. The electronic circuit of claim 15, further comprising an analog buffer having a power terminal and an output, the power terminal of the analog buffer coupled to the first supply voltage terminal, and the output of the analog buffer coupled to the control terminal of the first transistor.

17. The electronic circuit of claim 13, wherein the capacitor is a first capacitor, and the electronic circuit further comprises a second capacitor having a first terminal and a second terminal, the first terminal of the second capacitor coupled to the control terminal of the first transistor, and the second terminal of the capacitor coupled to a ground terminal.

18. A system comprising:
a controller; and
a laser driver coupled to the controller, the laser driver including:
a first transistor and a second transistor, the first transistor having a control terminal, and the second transistor having a control terminal; and
control circuitry having a first output terminal and a second output terminal, the first output terminal coupled to control terminal of the first transistor, and the second output terminal coupled to the control terminal of the second transistor, wherein the control circuitry is configured to:
provide a first charge to the first output terminal;
provide a second charge to the second output terminal based on an output of the controller; and
while providing the first charge to the first output terminal and the second charge at the second output terminal, apply a charge cancellation at the first output terminal responsive to the second charge at the second output terminal.

19. The system of claim 18, further comprising a photodiode coupled to the controller, wherein the controller is configured to determine a time-of-flight value based on an output of the photodiode and the output of the controller.

20. The system of claim 19, wherein the laser driver has an output terminal, the first transistor has a first current path terminal and a second current path terminal, the second transistor has a first current path terminal and a second current path terminal, the first current path terminal of the second transistor coupled to the output terminal of the laser driver, the second current path terminal of the second transistor coupled to the first current path terminal of the first transistor, the second current path terminal of the first transistor coupled to a ground terminal, and the system further comprises a laser diode having a first terminal coupled to the output terminal of the laser driver.

21. The system of claim 20, wherein the laser driver is part of an integrated circuit (IC) with the first transistor, the second transistor and the control circuitry, and the controller and the laser diode are separate from the IC.

22. The system of claim 18, wherein the control circuitry includes:
an inverter having an output;
a first non-overlapping driver circuit having an output coupled to the second output terminal of the control circuitry;
a second non-overlapping driver circuit having an output; and
a capacitor having a first terminal and a second terminal, the first terminal of the capacitor coupled to the output of the second non-overlapping driver circuit, and the second terminal of the capacitor coupled to the first output terminal of the control circuit.

23. The system of claim 22, wherein the first non-overlapping driver circuit has an input and power terminal, the second non-overlapping driver circuit has an input and a power terminal, the controller has a first terminal and a second terminal, and the control circuitry includes:
a low-dropout regulator (LDO) having a power terminal and an output, the power terminal of the LDO coupled to a first supply voltage terminal, the output of the LDO coupled to the power terminals of the first and second non-overlapping driver circuits;
a differential amplifier having a first input, a second input, and an output, the first input of the differential amplifier coupled to the first terminal of the controller, and the second input of the differential amplifier coupled to the second terminal of the controller;
a first inverter having an input, a power terminal, and an output, the input of the first inverter coupled to the output of the differential amplifier;
a second inverter having an input, a power terminal, and an output, the input of the second inverter coupled to the output of the first inverter; and
a third inverter having an input, a power terminal, and an output, the input of the third inverter coupled to the output of the second inverter, the output of the third inverter coupled to the inputs of the first and second non-overlapping driver circuits, and the power terminals of the first, second, and third inverters coupled to the first supply voltage terminal.
